(19) United States
(12) Patent Application Publication
(10) Pub. No.: US 2022/0024335 A1
(43) Pub. Date: Jan. 27, 2022

(54) ELECTRICAL CHARGE PATTERN VALIDATION

(71) Applicant: Ford Global Technologies, LLC, Dearborn, MI (US)

(72) Inventors: Ryan O'Gorman, Beverly Hills, MI (US); Mikolaj Stachura, Rochester Hills, MI (US); Aparna Velampudi, Troy, MI (US)

(21) Appl. No.: 16/938,638

(22) Filed: Jul. 24, 2020

(51) Int. Cl. B60L 53/62; G01R 21/06; H02J 7/00

(52) U.S. Cl. CPC B60L 53/62; H02J 7/00712; H02J 7/00032; G01R 21/06

(57) ABSTRACT

A charge validation system receives data defining a first temporal pattern of electrical parameter values describing electric power received during a charge event with a vehicle, receives data defining a second temporal pattern of electrical parameter values describing electric power supplied during a charge event with electric vehicle supply equipment, and responsive to mismatch of the first and second temporal patterns, sends a command to the electric vehicle supply equipment to prompt the electric vehicle supply equipment to discontinue or preclude charging.

### TECHNICAL FIELD

This disclosure relates to the charging of vehicle batteries.

### BACKGROUND

Electrified vehicles (EVs) including hybrid-electric vehicles (HEVs) and battery electric vehicles (BEVs) rely on a traction battery to provide power to a traction motor for propulsion and a power inverter therebetween to convert direct current (DC) power to alternating current (AC) power. These batteries may be charged via electric vehicle supply equipment.

### SUMMARY

A charge validation system includes one or more computer processors remote from a vehicle and electric vehicle supply equipment. The one or more computer processors receive data defining a first temporal pattern of electrical parameter values describing electric power received during a charge event with the vehicle, receive data defining a second temporal pattern of electrical parameter values describing electric power supplied during a charge event with the electric vehicle supply equipment, and responsive to mismatch of the first and second temporal patterns, send a command to the electric vehicle supply equipment to prompt the electric vehicle supply equipment to discontinue or preclude charging.

A charge validation method includes receiving data describing a first temporal pattern of electrical parameter values of electric power received during a charge event with a vehicle, receiving data describing a second temporal pattern of electrical parameter values of electric power supplied during a charge event with electric vehicle supply equipment, and responsive to mismatch of the first and second temporal patterns, sending a command to the electric vehicle supply equipment to prompt the electric vehicle supply equipment to discontinue or preclude charging.

A charge validation method includes receiving first data describing a time series of amplitude values of electric power received by a vehicle during a charge event, receiving second data describing a time series of amplitude values of electric power supplied by electric vehicle supply equipment during a charge event, and responsive to mismatch of the first and second data, sending a command to the electric vehicle supply equipment to prompt the electric vehicle supply equipment to discontinue charging

### BRIEF DESCRIPTION OF THE DRAWINGS

FIG. 1 is a schematic diagram of a vehicle charging environment.

FIG. 2 is a block diagram of an algorithm for validating charge information.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Electrical patterns can be used during a charging event to identify a specific party to the event. A designated pattern, e.g., an identifier, can be used when charging is initiated. The pattern can be simple to complex depending on its use, and generated in several ways: 1) the vehicle can draw electricity and that load can vary by time and amplitude creating a distinct temporal pattern of electrical parameter values, 2) the electric vehicle supply equipment (EVSE) can restrict or modulate the amount of electricity the vehicle can have to create a temporal pattern, or 3) electricity supplied to the EVSE can be modulated by a corresponding charge station. In case 3), the EVSE would receive modulated available power and that would simply flow through the EVSE to the vehicle. The EVSE and/or vehicle can record this temporal pattern of electrical parameter values by registering changes in amplitude of power being pulled by the vehicle or provided by the EVSE as a time sequence. A time stamp at each power level change could also be recorded.

The pattern need not be limited to step functions or static signals for durations of time, but could include dynamic measures such as ramp rate and changes in ramp rate, etc. Thus, numerous different signals could be generated. Also, the pattern could be generated for a minute or more if the vehicles or EVSEs cannot modulate electricity sufficiently fast.

The vehicle and/or EVSE may have the capability to modulate electrical flow. Both the vehicle and EVSE may have the capability to report the pattern to a cloud. The two patterns can be digitally matched remotely. This reduces the need for the vehicle to communicate directly with the EVSE or for there to be any sophisticated validation of patterns handled locally on the vehicle or EVSE.

The matching can be done in several ways, either the EVSE and vehicle have a common manufacturer or cloud provider and the validation can be done in one backend. Or, the vehicle's cloud could report to the EVSE's cloud for validation and vice versa. A third party cloud may also independently validate the patterns between the devices, or an owner/operator of either the EVSE and/or vehicle could perform the matching.

The pattern can also be dynamically updated for each authentication event to ensure security by a remote governing system or by the end device (EVSE or vehicle). In an example, a vehicle remote system can send a new, event specific pattern to the vehicle to use. The unique pattern would ensure identity yet, by being a transaction specific pattern issued for a specific event. it would ensure security of the solution. Similarly, the pattern can be controlled and defined by the EVSE governing remote system, third party remote system, the electric vehicle, or the connected charger.

A fleet manager may want to know who charges when, but for efficiency and accuracy may not likely want to require drivers to carry radio frequency identifiers, to use mobile applications, or to login to EVSEs. In this case a vehicle could be assigned a specific pattern to implement when charging is initiated. That vehicle when plugged into any depot charger will exhibit that pattern. With all charging events reported by the vehicle and depot EVSEs, a fleet manager can execute backend software to match the EVSEs and vehicles, and based on when the charging events occurred and operation schedule, identify the assigned vehicle operators, the amount of power used, etc. This scenario thus does not require a common hardware solution across manufacturers.

Fleet owners may have a negotiated rate for public charging with a charge point provider. An entire fleet may be assigned a specific pattern, or a portion of the pattern may identify the fleet and a second portion of the pattern could identify a specific driver or vehicle. This would allow a vehicle to charge at a public site and when the initialization pattern was exhibited in the charging event, the charge point provider could identify that user or group and provide a differentiated cost to the customer. This again could be done without using special purchase arrangements requiring a physical implement. It could also be post processed in a billing situation where all events that exhibited a certain key (pattern) would be calculated differently.

Key pattern matching could also be used for activation and identifying an individual or a group. For example, a dealer or retailer may offer charging to its customers for free, but not to others. The dealer could setup a charger to create a pattern. If a vehicle charges at the dealer and the pattern is not reported by the vehicle, the charging session could be stopped.

This capability could be used for public charging as well. Today, there is a plug and charge capability defined by a standard protocol. The protocol defines local requirements of the vehicle and EVSE including software, processing capability, and hardware to handle cyber security between the vehicle and EVSE. Once the identity (an encrypted key) of the vehicle is validated by the EVSE's backend, charging may start. Here, the local processing would not be necessary. If the vehicle reported a pattern to its backend and the EVSE independently reported its pattern to its own backend, and a third party independently validated or the EVSE backend validated the key patterns without the vehicle and EVSE directly communicating with one another, there would be a high level of security associated with identifying which vehicle is using the charger. It would be difficult to simultaneously compromise vehicle secure reporting and EVSE secure reporting to deliver the same key pattern to both backends for validation.

These solutions could also be done with an EVSE that is not connected. Similar to the dealer scenario, an owner may want to limit who uses their EVSE. If the EVSE was not connected, the pattern could be hard coded into the EVSE, or an upstream electricity controller could modulate the electrical supply to the EVSE. Then to use the EVSE, the vehicle would have to report its charging pattern to the EVSE owner's backend. If the EVSE is used and the pattern is not reported, the power to the EVSE could be turned off by a switch in the power supply to the EVSE preventing the vehicle from charging. If the vehicle is registered and reporting, charging will continue because the EVSE backend system will see the pattern validated.

Electric key patterns could also be used to differentiate vehicles charging at a bank of chargers. Global positioning satellite data, time, or some other metric could also be used to identify which vehicle is using which charger. To the extent there is risk for error, a key associated with one or more of those metrics would significantly reduce the risk of error. The key may change throughout the day or year, may have to be registered, may be used for filtering events, or may be a combination of identifiers. The key could be used independent of location and time if not used for event authorization, but in the event of authorization there would be some time based need to validate the reported patterns. This could include information from GPS, time, referenced EVSE, etc.

Keys could be tied to the operators. Digital key capability could automatically configure the vehicle to exhibit a specific electric key pattern when charging depending on who is using the vehicle. The pattern could securely be downloaded from the cloud when a digital key to enter the vehicle is recognized, or for fleets a vehicle could store the electric key pattern for all operators approved to charge vehicles.

If a customer has auto lock/unlock turned on, that is, when a vehicle is plugged into a box with access control on it, they will want to control which cars automatically unlock the box. Auto unlock will only be available for certain vehicles because other vehicles will not report their charging events. When wall box auto lock is turned on, the box can be set to start charging at a specific charge level. When certain vehicles plug in, they send a report to the backend. When charge rate changes, they send another report. After charge starts, the wall box can be sent a de-rate command. The vehicle will see the change in charge rate and report it. If the change in charging is not reported by an authorized vehicle, the box will lock and charging will be stopped.

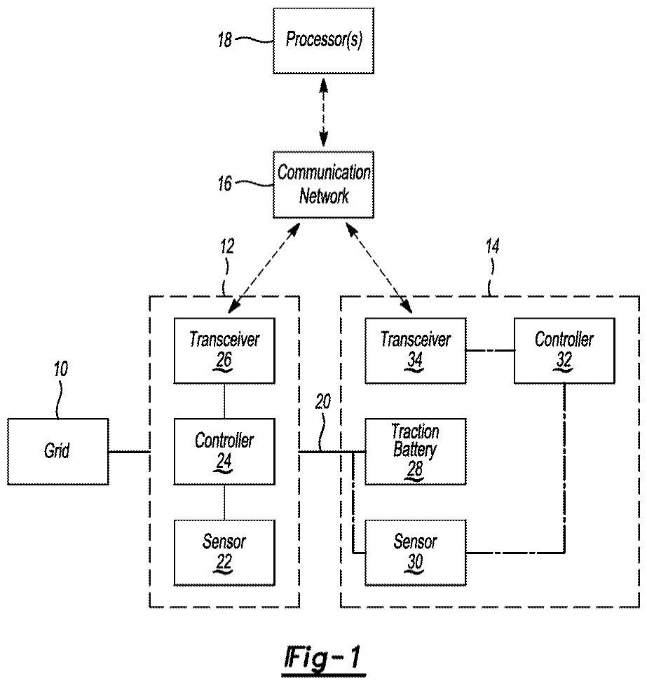

With reference to FIG. 1, an electrical grid 10, charge station 12, vehicle 14, communication network 16 (e.g., Internet, etc.), remote computer processor 18, and charge cord 20 are shown. The charge cord 20 electrically connects the charge station 12 and vehicle 14 as known in the art such that power from the grid 10 and flowing through the charge station 12 passes to the vehicle 14,

The charge station 12 includes a current and/or voltage sensor 22, controller 24, and transceiver 26. The sensor 22 and transceiver 26 are in communication with/under the control of the controller 24. The vehicle 14 includes a traction battery 28, current and/or voltage sensor 30, controller 32, and transceiver 34. The traction battery 28, sensor 30, and transceiver 34 are in communication with/under the control of the controller 32.

The sensor 22 is configured in known fashion to detect the current and/or voltage (amplitude) over time of power flowing through the charge station 12 from the grid 10 to the charge cord 20. This data, which describes a temporal pattern of electrical parameter values of electric charge power supplied during a charge event, is captured by the controller 24 and transmitted via the transceiver 26 to the communication network 16.

The sensor 30 is configured in known fashion to detect the current and/or voltage over time of power flowing from the charge cord 20 to the traction battery 28. This data, which describes a temporal pattern of electrical parameter values of electric charge power received during a charge event, is captured by the controller 32 and transmitted via the transceiver 34 to the communication network 16. Time stamps can be used by each of the charge station 12 and vehicle 14 to ensure that the data captured is from a same time period.

The processor 18 upon receiving the data from each of the charge station 12 and vehicle 14 via the communication network 16 may compare the temporal patterns to determine if they match. If amplitude values of the voltage supplied by the charge station 12 and received by the vehicle 14 are within, for example, five percent of each other for a same twenty second period, the patterns match. If any amplitude values of the current supplied by the charge station 12 and received by the vehicle 14 are more than, for example twenty percent different for a same instant in time, the patterns do not match. Other match/mismatch criteria are of course contemplated. A matched set of patterns would indicate that the vehicle 14 is indeed connected with and receiving power from the charge station 12. A mismatched set of patterns would indicate that the vehicle 14 is not connected with and receiving power from the charge station 12. If the patterns match, the processor 18 may send a command to the charge station 12 via the communication network 16 to initiate or continue charging. If the patterns do not match, the processor 18 may send a command to the charge station 12 via the communication network 16 to discontinue or preclude charging.

The processor 18 may also periodically take action to ensure the charge station 12 and vehicle 14 are connected together. The processor 18 may command the charge station 12 to change the current or voltage of the electric power being supplied and request the vehicle 14 to report its temporal pattern to determine whether the vehicle 14 detects the change in current or voltage. The processor 18 may command the charge station 12 to supply power yielding a predesignated temporal pattern or command the vehicle 14 to request power yielding a predesignated temporal pattern. Other scenarios are also possible.

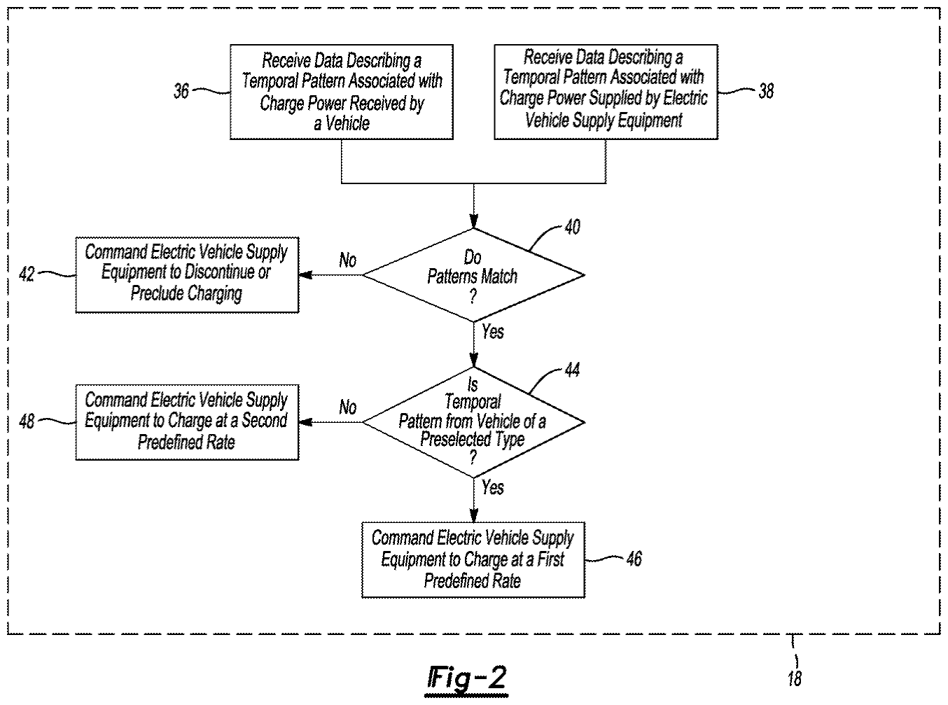

With reference to FIG. 2, data is received describing a temporal pattern associated with charge power received by a vehicle at operation 36, and data is received describing a temporal pattern associated with charge power supplied by electric vehicle supply equipment at operation 38. At decision block 40, it is determined whether the patterns match. If no, the electric vehicle supply equipment is commanded to discontinue charging at operation 42. If yes, it is determined whether the temporal pattern from the vehicle is of a preselected type at decision block 44 (e.g., Are the amplitude values all less than a predefined threshold value? Is the temporal pattern of a duration less than a predefined duration?, etc.) If yes, the electric vehicle supply equipment is commanded to supply charge at a first predefined rate at operation 46. If no, the electric vehicle supply equipment is commanded to supply charge at a second predefined rate at operation 48.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as Read Only Memory (ROM) devices and information alterably stored on writeable storage media such as floppy disks, magnetic tapes, Compact Discs (CDs), Random Access Memory (RAM) devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

The words used in the specification are words of description rather than limitation, and it is understood that various changes can be made without departing from the spirit and scope of the disclosure. The communication described with reference to FIG. 1 for example suggests that it be done in wireless fashion. Such communication, however, may be done in wired fashion, wireless fashion, or some combination of the two, etc. Moreover, electric vehicle supply equipment as used herein may contemplate a charge station, a charge cord (smart charge cord), or both. In the example of FIG. 1, the capability to detect, record, and send the pattern associated with power supplied is associated with the charge station 12. This capability, however, may also reside within the charge cord 20, or be distributed among the charge station 12 and cord 20, etc.

As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes may include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A charge validation system comprising:
one or more computer processors remote from a vehicle and electric vehicle supply equipment, and programmed to
receive data defining a first temporal pattern of electrical parameter values describing electric power received during a charge event with the vehicle,
receive data defining a second temporal pattern of electrical parameter values describing electric power supplied during a charge event with the electric vehicle supply equipment, and
responsive to mismatch of the first and second temporal patterns, send a command to the electric vehicle supply equipment to prompt the electric vehicle supply equipment to discontinue or preclude charging.

2. The charge validation system of claim 1, wherein the one or more computer processors are further programmed to, responsive to match of the first and second temporal patterns, send a command to the electric vehicle supply equipment to prompt the electric vehicle supply equipment to initiate or continue charging.

3. The charge validation system of claim 1, wherein the one or more computer processors are further programmed to,
responsive to the first temporal pattern being of a first type, send a command to the electric vehicle supply equipment to initiate or continue charging at a first rate, and
responsive to the first temporal pattern being of a second type, send a command to the electric vehicle supply equipment to initiate or continue charging at a second rate.

4. The charge validation system of claim 1, wherein the one or more computer processors are further programmed to send a command to the electric vehicle supply equipment to change a current or voltage of the electric power supplied.

5. The charge validation system of claim 1, wherein the one or more computer processors are further programmed to send a request to the vehicle for the data defining a first temporal pattern of electrical parameter values describing electric power received during a charge event with the vehicle.

6. The charge validation system of claim 1, wherein the one or more computer processors are further programmed to send a request to the electric vehicle supply equipment for the data defining a second temporal pattern of electrical parameter values describing electric power supplied during a charge event with the electric vehicle supply equipment.

7. The charge validation system of claim 1, wherein the one or more computer processors are further programmed to command the vehicle to request electric power having electrical parameter values defining a predesignated temporal pattern.

8. The charge validation system of claim 1, wherein the one or more computer processors are further programmed to command the electric vehicle supply equipment to supply electric power having electrical parameter values defining a predesignated temporal pattern.

9. A charge validation method comprising:
receiving data describing a first temporal pattern of electrical parameter values of electric power received during a charge event with a vehicle;
receiving data describing a second temporal pattern of electrical parameter values of electric power supplied during a charge event with electric vehicle supply equipment; and
responsive to mismatch of the first and second temporal patterns, sending a command to the electric vehicle supply equipment to prompt the electric vehicle supply equipment to discontinue or preclude charging.

10. The charge validation method of claim 9 further comprising, responsive to match of the first and second temporal patterns, sending a command to the electric vehicle supply equipment to prompt the electric vehicle supply equipment to initiate or continue charging.

11. The charge validation method of claim 9 further comprising responsive to the first temporal pattern being of a first type, sending a command to the electric vehicle supply equipment to continue charging at a first rate, and responsive to the first temporal pattern being of a second type, sending a command to the electric vehicle supply equipment to continue charging at a second rate.

12. The charge validation method of claim 9 further comprising sending a command to the electric vehicle supply equipment to change a current or voltage of the electric power supplied.

13. The charge validation method of claim 9 further comprising sending a request to the vehicle for the data describing a first temporal pattern of electrical parameter values of electric charge power received during a charge event of the vehicle.

14. The charge validation method of claim 9 further comprising sending a request to the electric vehicle supply equipment for the data describing a second temporal pattern of electrical parameter values of electric power supplied during a charge event with the electric vehicle supply equipment.

15. The charge validation method of claim 9 further comprising commanding the vehicle to request electric power having electrical parameter values defining a predesignated temporal pattern.

16. The charge validation method of claim 9 further comprising commanding the electric vehicle supply equipment to supply electric power having electrical parameter values defining a predesignated temporal pattern.

17. A charge validation method comprising:
receiving first data describing a time series of amplitude values of electric power received by a vehicle during a charge event;
receiving second data describing a time series of amplitude values of electric power supplied by electric vehicle supply equipment during a charge event; and
responsive to mismatch of the first and second data, sending a command to the electric vehicle supply equipment to prompt the electric vehicle supply equipment to discontinue charging.

18. The charge validation method of claim 17 further comprising, responsive to match of the first and second data, sending a command to the electric vehicle supply equipment to prompt the electric vehicle supply equipment to continue charging.
